(19) United States
(12) Patent Application Publication
(10) Pub. No.: US 2024/0222268 A1
(43) Pub. Date: Jul. 4, 2024

(54) SEMICONDUCTOR DEVICE HAVING CONTACT PLUG

(71) Applicant: MICRON TECHNOLOGY, INC., BOISE, ID (US)

(72) Inventors: TAKAYOSHI TASHIRO, Higashihiroshima (JP); HIROKI YAMAWAKI, Higashihiroshima (JP); AKIRA KANEKO, Higashihiroshima (JP)

(73) Assignee: MICRON TECHNOLOGY, INC., Boise, ID (US)

(21) Appl. No.: 18/483,748

(22) Filed: Oct. 10, 2023

Related U.S. Application Data
(60) Provisional application No. 63/477,621, filed on Dec. 29, 2022.

(51) Int. Cl. H01L 23/522; H01L 21/768; H01L 23/528; H01L 23/532

(52) U.S. Cl. CPC H01L 23/5226; H01L 21/7684; H01L 21/76843; H01L 21/76865; H01L 23/5283; H01L 23/53266

(57) ABSTRACT

An apparatus that includes a first interlayer insulating film having a contact hole; a contact plug embedded in the contact hole, the contact plug including a main part and a barrier metal part located between an outer wall of the main part and an inner wall of the contact hole; a second interlayer insulating film covering the first interlayer insulating film; and a first conductive pattern embedded in the second interlayer insulating film and connected to the contact plug. Apart of the second interlayer insulating film is embedded in a gap between a top part of the outer wall of the main part of the contact plug and a top part of the inner wall of the contact hole.

### CROSS REFERENCE TO RELATED APPLICATION(S)

This application claims priority to U.S. Provisional Application No. 63/477,621, filed Dec. 29, 2022. The aforementioned application is incorporated herein by reference, in its entirety, for any purpose.

### BACKGROUND

A general semiconductor device includes a plurality of wiring layers. Wiring patterns respectively formed in two wiring layers vertically adjacent to each other may cross and be connected to each other via a contact plug provided at a crossing. When the diameter of the contact plug is small, the contact resistance becomes high. When the diameter of the contact plug is large, the dielectric strength between a wiring pattern adjacent to the wiring pattern connected to the contact plug and the contact plug is reduced.

### BRIEF DESCRIPTION OF THE DRAWINGS

FIG. 1A is a schematic plan view showing a configuration of a main portion of a semiconductor device according to an embodiment of the present disclosure;

FIG. 1B is a schematic cross-sectional view taken along a line A-A in FIG. 1A; and

FIGS. 2A to 2F are process diagrams for explaining a manufacturing method of the semiconductor device according to the embodiment of the present disclosure.

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessary mutually exclusive, as some disclosed embodiments can be combined with one or more other disclosed embodiments to form new embodiments.

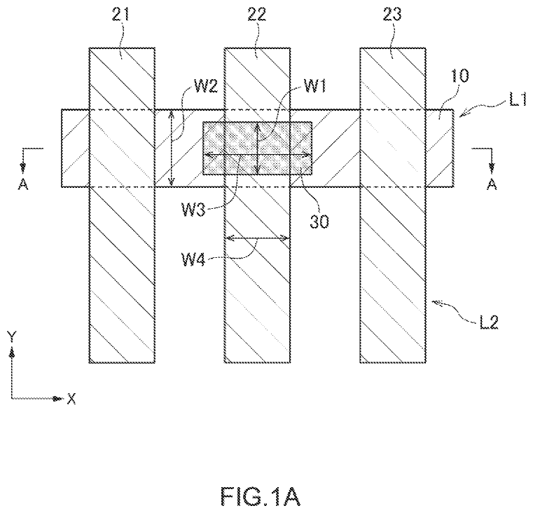

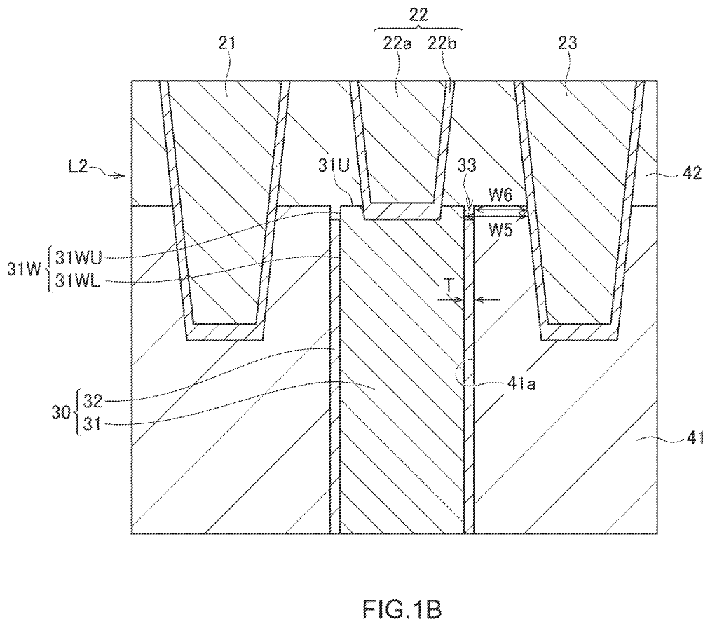

FIG. 1A is a schematic plan view showing a configuration of a main portion of a semiconductor device according to an embodiment of the present disclosure. FIG. 1B is a schematic cross-sectional view taken along a line A-A in FIG. 1A. As shown in FIG. 1A, the semiconductor device according to the present embodiment includes a wiring pattern 10 positioned at a conductor layer L1 and wiring patterns 21 to 23 positioned at a conductor layer L2. The conductor layer L1 is located below the conductor layer L2 and tungsten (W), for example, may be used as its material. The conductor layer L2 may be made of, for example, copper (Cu). The wiring pattern 10 positioned at the conductor layer L1 extends in the X direction, and the wiring patterns 21 to 23 positioned at the conductor layer L2 extend in the Y direction. In some examples, the X direction and the Y direction may be perpendicular to each other. The wiring pattern 10 and the wiring patterns 21 to 23 cross each other in plan view. A contact plug 30 is provided at a crossing between the wiring pattern 10 and the wiring pattern 22. The wiring pattern 10 and the wiring pattern 22 are thus short-circuited via the contact plug 30. A width W1 of the contact plug 30 in the Y direction at its bottom surface in contact with the wiring pattern 10 may be smaller than a width W2 of the wiring pattern 10 in the Y direction. Meanwhile, a maximum width W3 of the contact plug 30 in the X direction may be greater than a width W4 of the wiring pattern 22 in the X direction. By setting the width W3 to be larger than the width W4 in this manner, the resistance value of the contact plug 30 is reduced.

As shown in FIG. 1B, the wiring pattern 22 includes a main part 22a made of a metal, for example, copper (Cu) and a barrier metal part 22b formed on the surface of the main part 22a. This is the same for the other wiring patterns 21 and 23. The contact plug 30 is embedded in a via hole 41a provided on an interlayer insulating film 41 being located between the conductor layer L1 and the conductor layer L2. The interlayer insulating film 41 is made of silicon oxide, for example. The contact plug 30 includes a main part 31 made of a metal, for example, tungsten (W) and a barrier metal part 32 covering the surface of the main part 31. The barrier metal part 32 may be made of metallic nitride, for example, titanium nitride. An outer wall 31W of the main part 31 surrounded by the contact hole 41a includes a lower region 31WL covered by the barrier metal part 32 and an upper region 31WU not covered by the barrier metal part 32. Therefore, a gap 33 is formed between the upper region 31WU on the outer wall 31W of the main part 31 and an inner wall of the via hole 41a. An upper surface 31U of the main part 31 is not covered by the barrier metal part 32 and is in contact with the wiring pattern 22 and an interlayer insulating film 42.

The wiring patterns 21 to 23 are embedded in the interlayer insulating film 42 provided on the interlayer insulating film 41. The interlayer insulating film 42 is made of a material having a permittivity lower than a material constituting the interlayer insulating film 41, such as low-k material. In some examples, the second interlayer insulating film 42 has a lower dielectric constant than the first interlayer insulating film 41. In the cross-section shown in FIG. 1B, a part of the wiring pattern 21 or 23 is embedded in the interlayer insulating film 41. A part of the interlayer insulating film 42 is embedded in the gap 33. With this configuration, the diameter of the contact plug 30 becomes smaller locally in the upper region 31WU that is not covered by the barrier metal part 32. That is, the diameter of the contact plug 30 becomes smaller by a size corresponding to twice a thickness T of the barrier metal part 32 in the upper region 31WU. Therefore, if the entirety of the outer wall 31W of the main part 31 is covered by the barrier metal part 32, the shortest distance in the X direction between the contact plug 30 and the wiring pattern 21 or 23 is W6, whereas the shortest distance in the X direction between the contact plug 30 and the wiring pattern 21 or 23 is W5 (≈W6+T) in the present embodiment.

With this configuration, the distance in the X direction between the upper part of the contact plug 30 and the bottom of the wiring pattern 21 or 23 is increased by the thickness T of the barrier metal part 32. Therefore, even in a case where the distance in the X direction between the via hole 41a and the bottom of the wiring pattern 21 or 23 is shorter, the distance in the X direction between the upper part of the contact plug 30 and the bottom of the wiring pattern 21 or 23 is sufficiently ensured, so that a dielectric strength between them is ensured.

Next, a manufacturing method of the semiconductor device according to the present embodiment is described.

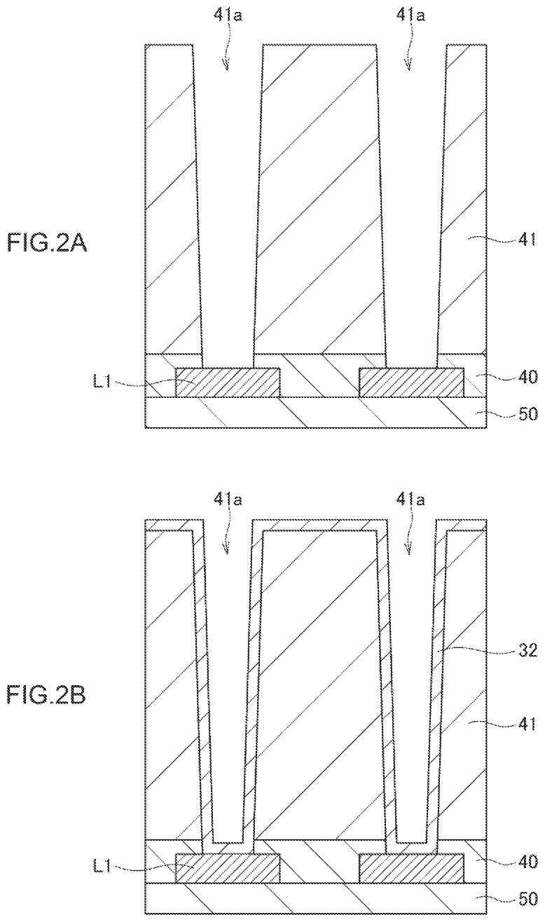

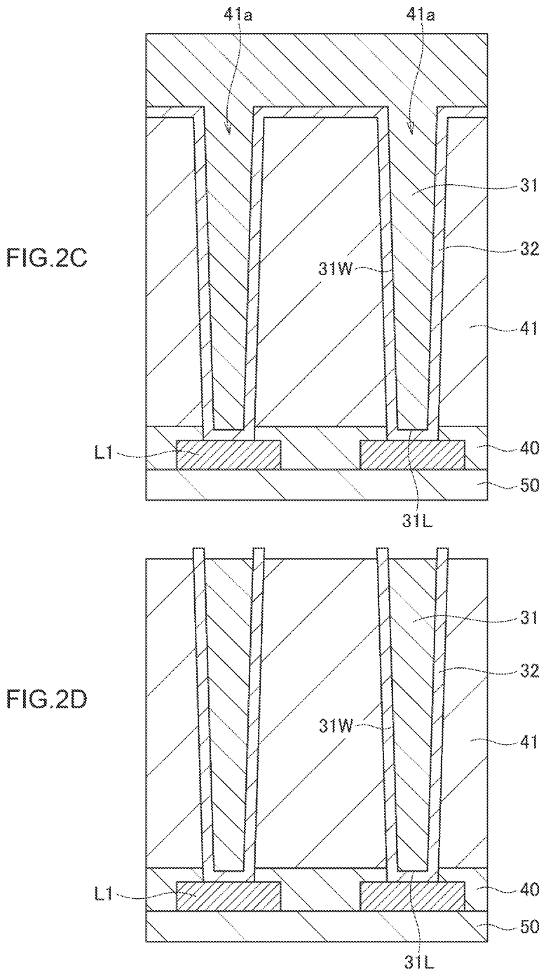

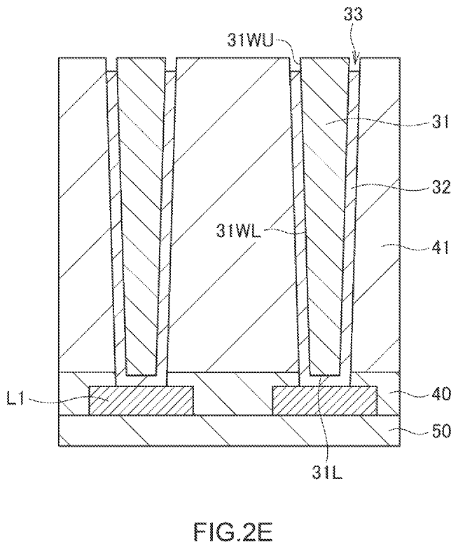

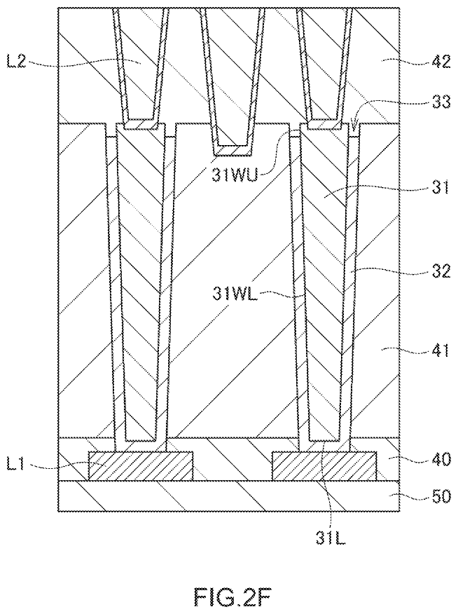

First, as shown in FIG. 2A, the via hole 41a is formed in the interlayer insulating films 40 and 41 covering the conductor layer L1. The interlayer insulating film 40 may be made of silicon nitride. The conductor layer L1 is formed on the surface of an interlayer insulating film 50 located lower than the interlayer insulating films 40 and 41. The conductor layer L1 is exposed at the bottom of the via hole 41a. Next, as shown in FIG. 2B, the barrier metal part 32 made of, for example, titanium nitride is deposited. With this processing, the bottom surface and the inner wall of the via hole 41a and the top surface of the interlayer insulating film 41 are covered by the barrier metal part 32. Next, as shown in FIG. 2C, the via hole 41a is embedded by the main part 31 of the contact plug 30 made of, for example, tungsten. The main part 31 of the contact plug 30 contacts with the barrier metal part 32 on the outer wall 31W and a bottom surface 31L.

Next, as shown in FIG. 2D, Chemical-mechanical Processing (CMP) is performed to remove the main part 31 of the contact plug 30 and the barrier metal part 32 formed on the upper surface of the interlayer insulating film 41. At this time, CMP is performed under a condition that the etching rate of the material constituting the main part 31 is higher than that of the material constituting the barrier metal part 32. With this processing, the upper part of the barrier metal part 32 slightly protrudes from the top surface of the interlayer insulating film 41. Next, as shown in FIG. 2E, the barrier metal part 32 is selectively etched. When the barrier metal part 32 is made of metallic nitride, for example, titanium nitride, etching on the barrier metal part 32 may be performed using heated sulfuric acid. With this processing, the etching rate of the barrier metal part 32 made of, for example, titanium nitride is higher than the etching rate of the main part 31 made of a metallic material, for example, tungsten. As a result, from the outer wall 31W of the main part 31 of the contact plug 30, the barrier metal part 32 covering the upper region 31WU is removed, and the gap 33 for exposing the upper region 31WU of the main part 31 is formed. Subsequently, as shown in FIG. 2F, the interlayer insulating film 42 covering the interlayer insulating film 41 is formed and the conductor layer L2 is formed in the interlayer insulating film 42. Since the interlayer insulating film 42 penetrates into the gap 33, the upper region 31WU of the main part 31 comes into contact with the interlayer insulating film 42.

As described above, in the present embodiment, since selective etching on the barrier metal part 32 is performed before forming the interlayer insulating film 42, it is possible to remove the barrier metal part 32 covering the upper region 31WU from the outer wall 31W of the main part 31 of the contact plug 30. Accordingly, a distance in the X direction between the upper part of the contact plug 30 and the bottom of the wiring pattern 21 or 23 can be sufficiently ensured.

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. An apparatus comprising:
a first interlayer insulating film having a contact hole;
a contact plug embedded in the contact hole, the contact plug including a main part and a barrier metal part located between an outer wall of the main part and an inner wall of the contact hole;
a second interlayer insulating film covering the first interlayer insulating film; and
a first conductive pattern embedded in the second interlayer insulating film and connected to the contact plug,
wherein a part of the second interlayer insulating film is embedded in a gap between a top part of the outer wall of the main part of the contact plug and a top part of the inner wall of the contact hole.

2. The apparatus of claim 1, further comprising a second conductive pattern covered with the first interlayer insulating film,
wherein the first and second conductive patterns are connected to each other via the contact plug,
wherein the first conductive pattern extend in a first direction, and
wherein the second conductive pattern extend in a second direction different from the first direction.

3. The apparatus of claim 2, further comprising a third conductive pattern embedded in the second interlayer insulating film,
wherein the first and third conductive patterns adjacently extend in parallel with each other.

4. The apparatus of claim 3, wherein a bottom of the third conductive pattern is embedded in the first interlayer insulating film.

5. The apparatus of claim 3, wherein a width of the contact plug in the second direction is greater than a width of the first conductive pattern in the second direction.

6. The apparatus of claim 1, wherein the barrier metal part of the contact plug comprises a different conductive material from the main part of the contact plug.

7. The apparatus of claim 6, wherein the barrier metal part of the contact plug comprises metal nitride.

8. The apparatus of claim 7, wherein the barrier metal part of the contact plug comprises titanium nitride.

9. The apparatus of claim 1, wherein the first interlayer insulating film comprises a different insulating material from the second interlayer insulating film.

10. The apparatus of claim 9, wherein the second interlayer insulating film has a lower dielectric constant than the first interlayer insulating film.

11. The apparatus of claim 10, wherein the second interlayer insulating film comprises low-k material.

12. An apparatus comprising:
a first conductive pattern positioned at a first wiring layer and extending in a first direction;
a second conductive pattern positioned at a second wiring layer located above the first wiring layer and extending in a second direction crossing the first direction; and
a contact plug connecting the first conductive pattern with the second conductive pattern,
wherein the contact plug includes;
a main part having a lower surface facing the first conductive pattern, an upper surface facing the second conductive pattern, and an outer wall surface located between the lower and upper surfaces, the outer wall surface including a lower section located at the lower surface side and an upper section located at the upper surface side; and
a barrier metal part covering the lower surface and the lower section of the outer wall surface of the main part without covering the upper surface and the upper section of the outer wall surface of the main part.

13. The apparatus of claim 12, further comprising:
a first interlayer insulating film located between the first and second wiring layers; and
a second interlayer insulating film covering the first interlayer insulating film so as to embed the second wiring layer therein,
wherein the upper section of the outer wall surface of the main part contacts with the second interlayer insulating film.

14. The apparatus of claim 13, wherein the second interlayer insulating film has a lower dielectric constant than the first interlayer insulating film.

15. The apparatus of claim 14, wherein the second interlayer insulating film comprises low-k material.

16. The apparatus of claim 12, wherein the barrier metal part of the contact plug comprises a different conductive material from the main part of the contact plug.

17. The apparatus of claim 16, wherein the surface part of the contact plug comprises metal nitride.

18. The apparatus of claim 17, wherein the surface part of the contact plug comprises titanium nitride.

19. A method comprising:
forming a contact hole in a first interlayer insulating film so as to expose a first conductive pattern covered with the first interlayer insulating film;
covering an inner wall of the contact hole with a first conductive material;
filling the contact hole with a second conductive material after the covering;
removing the first and second conductive materials on the first interlayer insulating film so as to expose atop part of the first and second conductive materials;
selectively removing the top part of the first conductive material so as to form a gap between the first interlayer insulating film and the top part of the second conductive material; and
forming a second interlayer insulating film on the first interlayer insulating film so as to fill the gap with the second interlayer insulating film; and
forming a second conductive pattern embedded in the second interlayer insulating film such that the second conductive pattern contacts with the top part of the second conductive material.

20. The method of claim 19,
wherein the first conductive material comprises metal nitride, and
wherein the selectively removing is performed by etching the first conductive material using sulfuric acid.
